(19) United States
(12) Patent Application Publication
(10) Pub. No.: US 2009/0303224 A1
(43) Pub. Date: Dec. 10, 2009

(54) LIQUID CRYSTAL DISPLAY DEVICE WITH A TIMING CONTROLLER AND MANUFACTURING THE SAME

(75) Inventor: Ikuko YOSHIDA, Ishikawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Toshiba Matsushita Display Technology, Tokyo (JP)

(21) Appl. No.: 12/419,485

(22) Filed: Apr. 7, 2009

(30) Foreign Application Priority Data
Jun. 4, 2008 (JP) 2008-147058

(51) Int. Cl. G09G 3/36; G09G 5/00; H01L 21/00

(52) U.S. Cl. 345/213; 345/99; 438/30; 257/E21.001

(57) ABSTRACT

A liquid crystal display device that includes a timing controller for outputting processed image signals to a source driver. The timing controller also includes a plurality of mapping circuits such as RSDS data mapping circuit and a mini-LVDS data mapping circuit. The mapping circuits are selectively connected to a differential amplitude generator by a switch element. The switch element is controlled by a control signal generated by a control signal generator formed and integrated on a printed circuit board separate from the timing controller. The switch element can additionally be controlled by automatically detecting a control signal from a source driver to select one of the mapping circuits after the timing controller is implemented in the liquid crystal display device.

### CROSS-REFERENCE TO RELATED APPLICATIONS

This application is based upon and claims the benefit of priority from prior Japanese Patent Application No. 2008-147058, filed Jun. 4, 2008, the entire contents of which are incorporated herein by reference.

### BACKGROUND OF THE INVENTION

1. Field of the Invention

The present invention relates generally to a liquid crystal display device, and more particularly to a timing controller applicable to the liquid crystal display device and is capable of reducing manufacturing cost.

2. Description of the Related Art

A liquid crystal display device includes a liquid crystal display panel having a pair of substrates facing each other such as an array substrate and a counter substrate, and a liquid crystal layer held therebetween. The liquid crystal display panel includes a plurality of pixels arranged in a matrix shape. The array substrate and the counter substrate include a pixel electrode corresponding to each pixel and a counter electrode facing the array substrate, respectively.

In a display area of the liquid crystal display panel, scan lines and signal lines are arranged in a row direction and a column direction of the pixel arrays. A gate driver and a source driver are also arranged in a periphery of the display area. The scan lines and the signal lines are connected to the gate driver and the source driver, respectively. An image signal and a clock signal from a timing controller are supplied to the source driver. The timing controller outputs the image signal and the clock signal to the source driver based on signals supplied from an outside signal source. The image signal is composed of a pair differential signals, which are outputted to the source driver from a pair of output terminals of the timing controller as shown in Japanese Laid Open Patent Application 2006-235452.

Conventionally, some differential driving systems such as a RSDS (Reduced Swing Differential Signaling) driving system and a mini-LVDS (mini-Low Voltage Differential Signaling) driving system are proposed as driving circuits using a pair of differential signals.

Recently, some controllers have been developed to meet requirements for such systems. For example, a timing controller that is provided with a RSDS transmitter is developed for exclusively outputting the RSDS signals in which the liquid crystal display device uses the RSDS driver as a source driver. Further, another controller that is provided with a mini-LVDS transmitter is developed for exclusively outputting mini-LVDS signals in which the liquid crystal display device uses a mini-LVDS driver as a source driver. The reason that two types of the timing controllers have to be developed is that specifications such as a data arrangement, a common voltage and an amplitude of a differential signal required for the timing controller is different from the RSDS type source driver and the mini-LVDS type source driver.

As described above, a different timing controller is used for the liquid crystal display device using a source driver with a different driving system. Therefore, if the liquid crystal display device adopts a source driver having a new driving system, it is necessary to develop a new timing controller, which may result in an increase of cost and longer development time of the liquid crystal display.

### BRIEF SUMMARY OF THE INVENTION

The present invention has been made to address the above mentioned problems.

An advantage of the present invention is to provide a liquid crystal display device including a timing controller usable for multiple types of source drivers, regardless of the types of source drivers implemented in the liquid crystal display device. According to the timing controller of this invention, the development cost can be reduced and the development time of the display can be also reduced.

One aspect of the invention is to provide a timing controller including: a logic circuit to receive an image signal and timing information from an outside signal source; a plurality of mapping circuits for receiving the output signal of the logic circuit; a differential amplitude generator to which an output signal from one of the plurality of mapping circuits is outputted; and a switch element for selectively connecting said one of the mapping circuits chosen from the plurality of circuits to the differential amplitude generator.

Another aspect of the invention is to provide a liquid crystal display device including: a pair of substrates; a liquid crystal layer held between the substrates; a display area including a plurality of pixels arranged in a matrix shape; a gate driver to select pixels arranged in a row line; a source driver to supply image signals to the pixels in the selected row line by the gate driver; and a timing controller including, a logic circuit for receiving an image signal and a timing signal from an outside signal source, a plurality of mapping circuits, a differential amplitude generator to which an output signal of one of the plurality of mapping circuits is supplied, and a switch element to selectively connect a singular mapping circuit chosen from the plurality of circuits to the differential amplitude generator.

Other aspect of the invention is to provide a method for manufacturing a liquid crystal display device including the steps: providing a liquid crystal display panel including a display area having a plurality of pixels arranged in a matrix shape, a gate driver to select pixels arranged in a row line, a source driver to supply image signals to the pixels arranged in the selected row line by the gate driver; forming a timing controller including a plurality of mapping circuits to output image data to a differential amplitude generator, the differential amplitude generator outputting differential signals to the source driver through output pins provided at a periphery of the timing controller; implementing the timing controller on a circuit board; and selectively connecting one of the plurality of mapping circuits to the differential amplitude generator by a switching element, wherein the switching element is controlled by a control signal supplied from a control terminal provided at a periphery of the timing controller; and wherein the differential amplitude generator includes a differential amplitude adjustment circuit and a common voltage adjustment circuit.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated into and constitute a part of the specification, illustrate presently preferred embodiments of the invention, and together with the general description given above and the detailed description of the embodiments given below, serve to explain the principles of the invention.

FIG. 1 is a diagram schematically showing the construction of a liquid crystal display device according to an embodiment of the present invention;

FIG. 2 is a diagram showing a flow of signals from an outside signal source to a source driver of the liquid crystal display device shown in FIG. 1;

FIG. 3 is an arrangement of image data that is supplied from a logic circuit to data mapping circuits of the liquid crystal display device shown in FIG. 2;

FIG. 4 is an arrangement of image data that is supplied from a RSDS data mapping circuit to a RSDS source driver of the liquid crystal display device shown in FIG. 2;

FIG. 5 is an arrangement of image data that is supplied from a mini-LVDS data mapping circuit to a mini-LVDS source driver of the liquid crystal display device shown in FIG. 2;

FIG. 6 is a table showing the correspondence between differential output signals and output pins of the timing controller in the liquid crystal display device shown in FIG. 2; and

FIG. 7 is a diagram showing a construction for a switching operation so as to select either one of the RSDS data mapping circuit and the mini-LVDS mapping circuit.

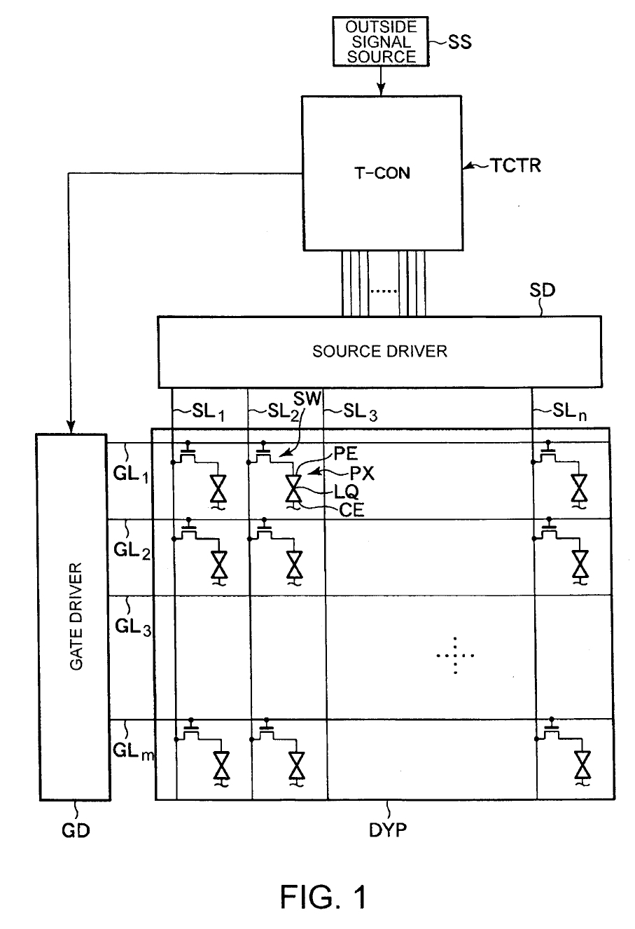

### DETAILED DESCRIPTION OF THE INVENTION

A liquid crystal display device according to an exemplary embodiment of the present invention, in particular, a timing controller for supplying image signals and timing signals to a source driver and the method for manufacturing the same will now be described with reference to the accompanying drawings.

A color type liquid crystal display device according to the present invention includes a pair of electrode substrates such as an array substrate, a counter substrate and a liquid crystal layer held therebetween. Further, the liquid crystal display device includes a display area DYP having a plurality of pixels arranged in a matrix shape, a gate driver GD and a source driver SD arranged in a periphery of the display area DYP, and a timing controller TCTR for controlling the gate and source drivers.

The display area DYP of the array substrate includes scan lines GL1˜GLm along the pixels PX arranged in a row direction and signal lines SL1˜SLn along the pixels PX arranged in a column direction. Where the scan lines cross with the signal lines, switching transistors SW are formed to correspond with each pixel PX. Each of the switching transistors SW includes a thin film transistor. The gate electrodes of the switching transistors SW are electrically connected to the corresponding scan lines, respectively. Similarly, a source electrode and a drain electrode of the switching transistors SW are connected to the corresponding signal lines SL1˜SLn and the pixel electrodes PE formed in each pixel, respectively.

The gate driver GD, controlled by a signal supplied from the timing controller TCTR, is connected to the scan lines GL1˜GLm so as to select one of the scan lines GL1˜GLm, successively. The source driver SD controlled by a signal supplied from the timing controller TCTR, is additionally connected to the signal lines SL1˜SLn to supply image signals to each of the signal lines SL1˜SLn. The timing controller TCTR is fixed on a printed circuit board (PCB) with other ICs. When one of the scan lines GL1˜GLm is selected by the gate driver GD, the switching transistors connected to the selected scan line are rendered conductive and the image signals are supplied to the respective pixel electrodes PE of the selected pixels PX arranged on the respective row. The counter substrate includes a counter electrode CE facing the plurality of pixel electrodes PE of the array substrate. A common voltage is supplied to the counter electrode CE. An alignment condition of liquid crystal molecular in the liquid crystal layer LQ is controlled by a voltage difference between a common voltage and a voltage supplied to the pixel electrode PE.

In an embodiment of this invention, a logic circuit 10 receives an image signal and a clock signal from an outside signal source SS and outputs image signals to a RSDS data mapping circuit 12 and a mini-LVDS data mapping circuit 14.

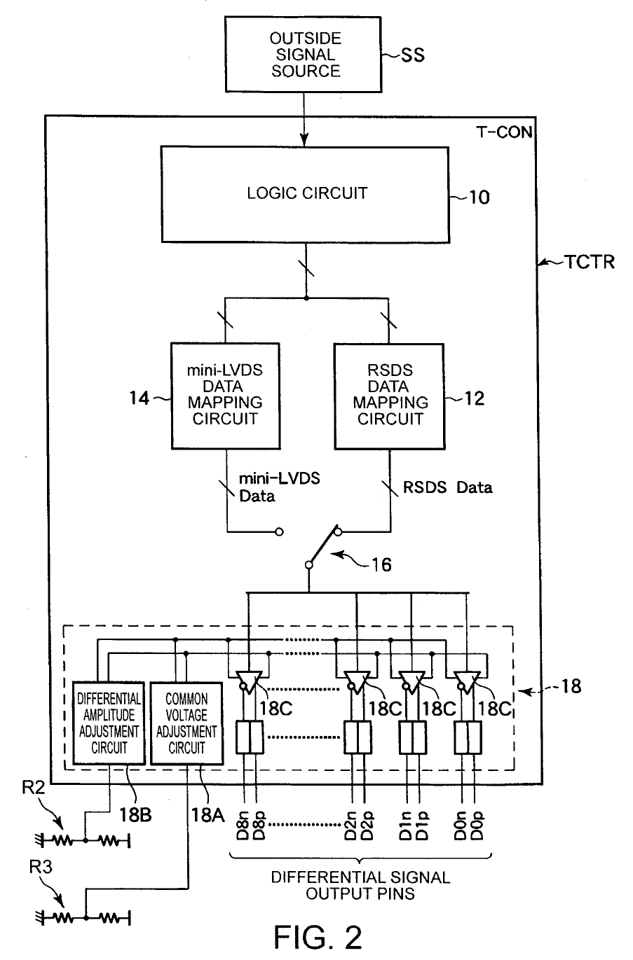

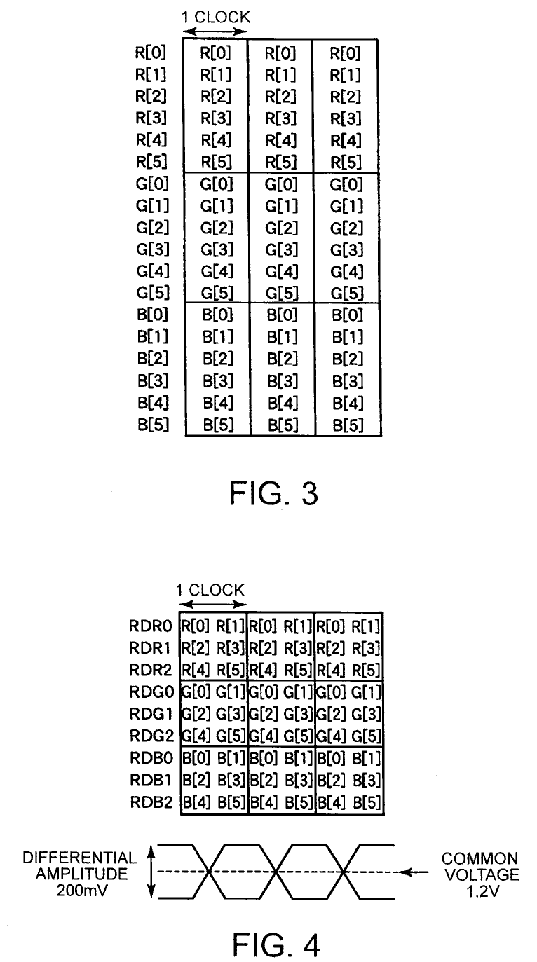

When the source driver SD selects a RSDS driver using six sets of bit data, the source driver SD requests the timing controller TCTR to supply specific data which includes a data arrangement, a common voltage and a differential amplitude. In the source driver SD using the six sets of bit data shown in FIG. 4, the timing controller TCTR supplies a differential signal to meet each request by the source driver SD upon receiving the output signal as shown in FIG. 3 from the logic circuit 10 shown in FIG. 2, in which the common voltage is 1.2 V and the differential amplitude is 200 mV.

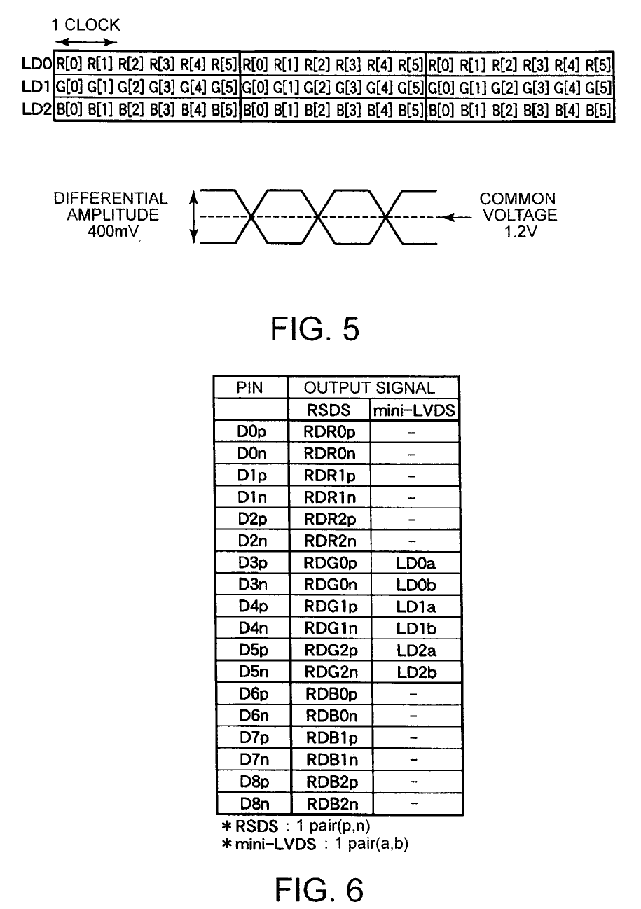

Alternatively, when the source driver SD selects a mini-LVDS driver using six sets of bit data, the source driver SD requests the timing controller TCTR to supply specific data which includes a data arrangement, a common voltage and a differential amplitude. In the source driver SD using six sets of bit data shown in FIG. 5, the timing controller TCTR supplies a differential signal so as to meet the request by the source driver SD upon receiving the output signal as shown in FIG. 3 of the logic circuit 10 shown in FIG. 2, in which the common voltage is 1.2 V and the differential amplitude is 400 mV.

According to the embodiment of the invention, the timing controller TCTR supplies the amplified differential signals to the source driver SD corresponding to the specification requested by the source driver SD. Meanwhile, the timing controller TCTR includes the logic circuit 10, two mapping circuits 12 and 14 and a differential amplitude generator 18. The logic circuit 10 includes horizontal and vertical timing controllers, a gradation adjusting circuit and other necessary embodiments. An outside signal from an outside signal source SS is supplied to the logic circuit 10 and then the logic circuit 10 processes the inputted outside signals to supply the processed signals to the mapping circuits 12 and 14. That is, when six sets of bit data are used for single pixel, the logic circuit 10 outputs following six bit image data, R[0]˜R[5], G[0]˜G[5] and B[0]˜B[5 ] for red, green and blue colors during one clock cycle, respectively.

In a color type liquid crystal display device, the logic circuit 10 outputs image data R[0] R[5] for pixels displaying red color, image data G[0]˜G[5] for pixels displaying green color, and image data B[0]˜B[5] for pixels displaying blue color, as shown in FIG. 3, respectively. An output terminal of the logic circuit 10 is connected to input terminals of both a RSDS data mapping circuit 12 and a mini-LVDS data mapping circuit 14. The RSDS data mapping circuit 12 rearranges the data received from the logic circuit 10 to meet the specification of the source driver SD and outputs rearranged data to the source driver SD.

For example, when the six bit image data for pixels of Red, Green, or Blue shown in FIG. 3 is inputted to a RSDS data mapping circuit 12, a RSDS data mapping circuit 12 outputs rearranged data as shown in FIG. 4. The RSDS data mapping circuit 12 rearranges the received data to output a unit of image data for the Red, Green, and/or Blue pixels, each having six bits, during a single clock cycle. The RSDS data mapping circuit 12 rearranges the received image data R[0] and data R[1] to output data R[0] during the first half cycle, and data R[1] during the second half cycle of a single clock cycle, respectively, as an output signal RDR0. The output signal RDR0 is outputted to a pair of differential signal output pins D0 (p, n) as shown in FIG. 6. Similarly, data R[2], data R[3], data R[4] and data R[5] are outputted to differential signal output pins D1 (p, n) and D2 (p, n) as output signals RDR1 and RDR2, respectively. As described above, the RSDS data mapping circuit 12 rearranges the inputted data R[0]˜R[5], G[0]˜G[5], and B[0]˜B[5] to a format which the source driver SD has requested.

The mini-LVDS data mapping circuit 14 rearranges the received image data from the logic circuit 10 to meet the specification requested by the mini-LVDS source driver. That is, a mini-LVDS data mapping circuit 14 outputs a unit of image data for Red, Green, and/or Blue pixels, each having six bits, during three clock cycles as shown in FIG. 5. The mini-LVDS data mapping circuit 14 rearranges the received image data R[0] and data R[1] to output data R[0] during the first half cycle, and data R[1] during the second half cycle of the first clock cycle. Similarly, data R[2] and data R[3] is outputted during the second clock cycle and data R[4] and data R[5] is outputted during the third clock cycle. The six bit of data is outputted to a pair of differential signal output pins D3 (p, n) as a differential amplified output signal LD0. Six bit image data G[0]˜G[5] and B[0]˜B[5] is outputted to the differential signal output pins D4 (p, n) and D5 (p, n) during three clock cycles as output signals LD1 and LD2, respectively.

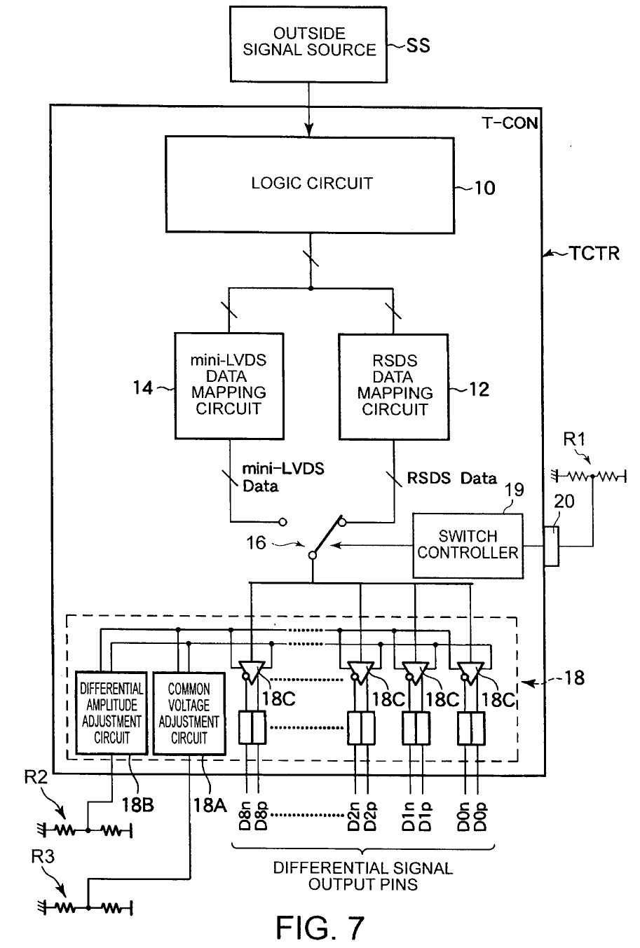

As shown in FIG. 7, a connection between the output terminals of the RSDS data mapping circuit 12 and the mini-LVDS data mapping circuit 14 and the input terminal of the differential amplitude generator 18 is switched over by a controllable switch element 16. The timing controller TCTR includes a switch controller 19 for controlling the switching operation between the mapping circuits 12 and 14 to the differential amplitude generator 18. A switch control signal is supplied to a control terminal 20 provided at a periphery of the timing controller TCTR. The voltage values of the switch control signal correspond to the connection to the RSDS data mapping circuit 12 or the mini-LVDS data mapping circuit 14, respectively. A bias resistor R1 is formed and integrated on the printed circuit board (PCB) and connected to the control terminal 20.

The resistance value of the bias resistor R1 is predetermined in order to properly select either mapping circuit 12 or 14, which is connected to the differential amplitude generator 18. As a consequence, when the source driver SD adopts the RSDS driver system, the output terminal of the RSDS data mapping circuit 12 is connected to the differential amplitude generator 18 corresponding to a resistance value of the bias resistor R1. Alternatively, when the source driver circuit SD adopts the mini-LVDS drive system, the output terminal of the mini-LVDS data mapping circuit 14 is connected to the differential amplitude generator 18 corresponding to another resistance value of the bias resistor R1.

Further, the connection between the mapping circuits 12 and 14 and the differential amplitude generator 18 can also be changed by automatically detecting a requested signal with some specifications from the source driver SD after the timing controller TCTR is implemented in the liquid crystal display device.

The differential amplitude generator 18 includes a common voltage adjustment circuit 18A, a differential amplitude adjustment circuit 18B, a plurality of differential signal amplifiers 18c, and differential signal output pins D0 (p, n)˜D8 (p, n), which are commonly used to transfer the outputted date for the RSDS driver and the mini-LVDS driver.

Each of the differential signal amplifiers 18c is connected to a bias resistor R3 through a common voltage adjustment circuit 18A. A bias resistor R3 is formed and integrated on the printed circuit board (PCB) separate from the timing controller TCTR. The common voltage of the differential amplified signal can be adjusted by selecting a resistance value of the bias resistor R3. In this embodiment, the resistance value of the bias resistor R3 for adjusting the common voltage is selected so that the common voltage is 1.2V for both the RSDS driver 12 and the mini-LVDS 14 driver used in the source driver SD.

Further, each of the differential signal amplifiers 18c is connected to a differential amplitude adjustment circuit 18B. A bias resistor R2 for adjusting the amplitude of the differential amplified signal is also connected to the differential amplitude adjustment circuit 18B. The bias resistor R2 is formed and integrated on the printed circuit board (PCB) separate from the timing controller TCTR. The amplitude of the differential amplified signal can be set at a predetermined value by selecting the resistance value of the bias resistor R2. When the source driver SD adopts the RSDS driver, the resistance value of the bias resistor R2 for adjusting the amplitude of the differential amplified signal is selected so that the amplitude of the differential amplitude signal is 200 mV for the RSDS drive used in the source driver SD. On the other hand, when the source driver SD adopts the mini-LVDS driver, the resistance value of the bias resistor R2 for adjusting the amplitude of the differential amplified signal is selected so that the amplitude of the differential amplified signal is 400 mV for the mini-LVDS driver used in the source driver SD.

Further, the image data outputted from the mapping circuits 12 and 14 is supplied to each differential signal amplifier 18c. The differential signal amplifier 18c having a pair of output terminals outputs a pair of differential signals from the output pins to the source driver SD. For example, when the source driver SD adopts the RSDS driver, the amplified differential signals are outputted from the output pins D0 (p, n)˜D8 (p, n). For example, a pair of amplified differential signals RDR0p and RDR0n corresponding to the output signal of the RSDS mapping circuit 12 are outputted from the output pins D0 (p, n) to the source driver SD.

When the source driver adopts the mini-LVDS, the amplified differential signals are outputted from the output pins D3 (p, n)˜D5 (p, n). For example, a pair of differential amplified signals LD0a and LD0b corresponding to the output signals of the mini-LVDS mapping circuit 14 are outputted from the output pins D3 (p, n).

As described above, each of the differential signal amplifiers 18c outputs image data, R[0]˜R[5], G[0]˜G[5] and B[0]˜B[5] as supplied from mapping circuits 12 and 14, to the source driver SD through the differential signal output pins. The output signals meet the specification requested by the source driver SD.

According to the embodiment of this invention, the timing controller TCTR includes a plurality of mapping circuits that are possible to meet several specifications requested by different source drivers SD by selecting a mapping circuit by the switching element. According to the liquid crystal display device in this invention, since some mapping circuits are pre-implemented in the timing controller, the timing controller TCTR can be applied to different types of source drivers SD regardless of the types of source drivers SD, which results in lower production cost and shorter developing time.

The present invention is not limited to the above-described embodiments. In practice, the structural elements can be modified without departing from the spirit of the invention. In the above embodiment, the timing controller TCTR includes the RSDS data mapping circuit 12 and the mini-LVDS mapping circuit 14. However, other mapping circuit, for example, a LVDS mapping circuit as one of the plurality of mapping circuits, can be utilized without limitation to the data mapping circuits such as the RSDS data mapping circuits 12 and the mini-LVDS mapping circuit 14. In other mapping circuits, same advantages as the above embodiments can be obtained by providing a switch element for changing the connections between the output terminals of the plurality of data mapping circuits and the input terminals of the differential amplitude generator.

Various inventions can be made by properly combining the structural elements disclosed in the embodiments. For example, some structural elements may be omitted from all the structural elements disclosed in the embodiments. Furthermore, structural elements in different embodiments may properly be combined.

What is claimed is:

1. A timing controller comprising:
a logic circuit to receive an image signal and a clock from an outside signal source;
a plurality of mapping circuits to receive an output signal from the logic circuit;
a differential amplitude generator to which an output signal of one of the plurality of mapping circuits is outputted; an
a switch element to selectively connect said one of the mapping circuits to the differential amplitude generator.

2. The timing controller according to claim 1, wherein the plurality of mapping circuits include an RSDS data mapping circuit.

3. The timing controller according to claim 1, wherein the plurality of mapping circuits include a mini-LVDS data mapping circuit.

4. The timing controller according to claim 1, wherein the differential amplitude generator includes a differential amplitude adjustment circuit and the timing controller further includes a bias resistor connected to the differential amplitude adjustment circuit to adjust the amplitude.

5. The timing controller according to claim 1, wherein the differential amplitude generator includes a common voltage adjustment circuit and the timing controller further includes a bias resistor connected to the common voltage adjustment circuit to adjust the common voltage.

6. The timing controller according to claim 1, wherein the switch element is controlled by a switch control signal supplied from a control terminal provided at a periphery of the timing controller.

7. A liquid crystal display device comprising:
a pair of substrates;
a liquid crystal layer held between the substrates;
a display area including a plurality of pixels arranged in a matrix shape;
a gate driver to select pixels arranged in a row line;
a source driver to supply image signals to the pixels arranged in the selected row line by the gate driver; and
a timing controller including,
a logic circuit to receive an image signal and a clock from an outside signal source,
a plurality of mapping circuits,
a differential amplitude generator to which an output signal of one of the plurality of mapping circuits is supplied, and
a switch element to selectively connect said one of the mapping circuits to the differential amplitude generator.

8. The liquid crystal display device according to claim 7, wherein the plurality of mapping circuits includes a RSDS data mapping circuit.

9. The liquid crystal display device according to claim 7, wherein the plurality of mapping circuits includes a mini-LVDS data mapping circuit.

10. The liquid crystal display device according to claim 7, wherein the differential amplitude generator includes a common voltage adjusting circuit and a differential amplitude adjustment circuit.

11. The liquid crystal display device according to claim 7, wherein the switch element is controlled by a switch control signal supplied from a control terminal provided at a periphery of the timing controller.

12. The timing controller according to claim 7, wherein the switch element is controlled by automatically detecting a control signal from the source driver.

13. A method for manufacturing a liquid crystal display device comprising the steps:
(a) providing a liquid crystal display panel including a display area having a plurality of pixels arranged in a matrix shape, a gate driver to select pixels arranged in a row line, a source driver to supply image signals to the pixels arranged in the selected row line by the gate driver;
(b) forming a timing controller including a plurality of mapping circuits to output image data to a differential amplitude generator, a differential amplitude generator outputting differential signals to a source driver through output pins provided at a periphery of the timing controller; and
(c) selectively connecting one of the plurality of mapping circuits to the differential amplitude generator by a controllable switching element.

14. The method for manufacturing a liquid crystal display device according to claim 13, wherein the switch element is controlled by a switch control signal supplied from a control terminal provided at a periphery of the timing controller.

15. The method for manufacturing a liquid crystal display device according to claim 13, wherein the switch element is controlled by automatically detecting a control signal from the source driver after the timing controller is implemented in the liquid crystal display device

16. The method for manufacturing a liquid crystal display device according to claim 13, wherein the plurality of mapping circuits include a RSDS data mapping circuit and a mini-LVDS data mapping circuit.

17. The method for manufacturing a liquid crystal display device according to claim 13, wherein the differential amplitude generator includes a differential amplitude adjustment circuit and the liquid crystal display device further includes a bias resistor connected to the differential amplitude adjustment circuit to adjust the amplitude.

18. The method for manufacturing a liquid crystal display device according to claim 13, wherein the differential amplitude generator includes a common voltage adjustment circuit and the liquid crystal display device further includes a bias resistor connected to the common voltage adjustment circuit to adjust the common voltage.

19. A method for manufacturing a liquid crystal display device comprising, in general, the following steps:
(a) providing a liquid crystal display panel including a display area having a plurality of pixels arranged in a matrix shape, a gate driver to select pixels arranged in a row line, a source driver to supply image signals to the pixels in the selected row line by the gate driver;
(b) forming a timing controller including a plurality of mapping circuits to output image data to a differential amplitude generator, a differential amplitude generator outputting differential signals to the source driver through output pins provided at a periphery of the timing controller;
(c) implementing the timing controller on a circuit board; and
(d) selectively connecting one of the plurality of mapping circuits to the differential amplitude generator by a switching element, wherein the switching element is controlled by a control signal supplied from a control terminal provided at a periphery of the timing controller; and
wherein the differential amplitude generator includes a differential amplitude adjustment circuit and a common voltage adjustment circuit.

20. The method for manufacturing a liquid crystal display device according to claim 19, further comprising a control signal generator provided on a printed circuit board separate from the timing controller, and
wherein the control signal generator generates a control signal that is supplied to a control terminal arranged at a periphery of the timing controller and a bias resistor is connected to the control terminal, and
wherein the resistance value of the bias resistor is predetermined so as to select one of the connections between the mapping circuits and the differential amplitude generator.
